(19) United States
(12) Patent Application Publication
(10) Pub. No.: US 2026/0363135 A1
(43) Pub. Date: Nov. 12, 2026

(54) HIGH ELECTRON MOBILITY TRANSISTOR ISOLATION WITH SURFACE PROTECTION

(71) Applicant: TEXAS INSTRUMENTS INCORPORATED, Dallas, TX (US)

(72) Inventors: Zhikai Tang, Sunnyvale, CA (US); Chang Soo Suh, Allen, TX (US); Shoji Wada, McKinney, TX (US); Eugene Reznik, Frisco, TX (US)

(21) Appl. No.: 19/205,866

(22) Filed: May 12, 2025

(51) Int. Cl. H10W 74/10; H10D 30/01; H10D 30/47; H10D 62/85

(52) U.S. Cl. CPC H10W 74/137; H10D 30/015; H10D 30/475; H10D 62/8503; H10W 74/147

(57) ABSTRACT

A semiconductor device includes, in part, a semiconductor layer, a barrier layer on the semiconductor layer, a gate layer on the barrier layer, and a dielectric layer on the gate layer. At least one of the barrier layer, the gate layer, or the dielectric layer has a carbon concentration of 1×10¹⁶ cm⁻³ or less. The dielectric layer and the gate layer may have the same footprint. The semiconductor device may include, in part, a second dielectric layer covering the barrier layer, the first dielectric layer, and the gate layer. The semiconductor device may further include, in part, an isolation region and an active region, with the gate layer being on the active region. The isolation region may extend at least across the barrier layer and the channel layer. The isolation region may extend into a first portion of the dielectric layer.

### BACKGROUND

A high electron mobility transistor (HEMT) may include a heterojunction near which a channel may be formed. The heterojunction may be formed using different semiconductor materials. The channel may be turned on or off by applying an appropriate voltage to a gate structure. Gallium nitride (GaN)-based HEMT devices generally have a high breakdown field, high electron mobility, low resistance, high current, faster-switching speed, high thermal conductivity, and excellent reverse-recovery performance, and thus may be suitable for applications where a low-loss and high-efficiency performance is desired, such as power electronics (e.g., power switches), radio frequency (RF) circuits, and the like.

### SUMMARY

This Summary is provided to introduce examples of disclosed concepts in a simplified form, which are further described below in the Detailed Description including the drawings provided.

According to certain aspects, a semiconductor device may include, in part, a semiconductor layer, a barrier layer on the semiconductor layer, a gate layer on the barrier layer, and a dielectric layer on the gate layer. At least one of the barrier layer, the gate layer or the dielectric layer may have a carbon concentration of 1×10¹⁶ cm⁻³ or less.

According to certain aspects, a semiconductor device may include, in part, a semiconductor layer with opposing first and second surfaces. The semiconductor layer may include, in part, an isolation region and an active region. The semiconductor device may further include, in part, a barrier layer on the first surface of the semiconductor layer. The isolation region extends into the barrier layer. The isolation region may include ions. The concentration of the ions within the isolation region may peak at a depth below a surface of the barrier layer and drop from the depth towards the surface. The concentration of the ions at the surface may be at least 10% of the concentration of the ions at the depth. The semiconductor device may further include, in part, a gate layer on the barrier layer and in the active region, and a dielectric layer on the gate layer.

According to certain aspects, a semiconductor device may include, in part, a semiconductor layer including an isolation region and an active region, a barrier layer on the semiconductor layer, a gate layer on the barrier layer and in the active region, and a dielectric layer on the gate layer. The isolation region extends into a first portion of the dielectric layer. A second portion of the dielectric layer over the active region has different chemical compositions from the first portion.

According to certain aspects, a method includes, in part, forming a gate layer on a barrier layer and a semiconductor layer, forming a dielectric layer on the gate layer, forming a photoresist layer on the dielectric layer and in which the dielectric layer separates the gate layer from the photoresist layer, patterning the photoresist layer, performing an ion implantation operation on parts of the barrier layer and the semiconductor layer under the patterned the photoresist layer, and removing the patterned photoresist layer.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim. The foregoing, together with other features and examples, will be described in more detail below in the following specification, claims, and accompanying drawings. This Summary is provided to introduce examples of disclosed concepts in a simplified form, which are further described below in the Detailed Description including the drawings provided.

### BRIEF DESCRIPTION OF THE DRAWINGS

Illustrative examples are described in detail below with reference to the following figures.

FIG. 1A is a cross-sectional view of a high electron mobility transistor (HEMT) being biased to conduct current, according to some examples.

FIG. 1B shows the drain-to-source current as a function of the drain-to-source voltage of the transistor of FIG. 1A under normal and high voltage conditions.

FIG. 2A is a plan view of a semiconductor device, according to some examples.

FIG. 2B is a perspective view of the semiconductor device of FIG. 2A, according to some examples.

FIGS. 3A, 3B, 3C, and 3D are cross-sectional views of a semiconductor device during various semiconductor fabrication processing steps, according to some examples.

FIG. 3E is a plot of an ion profile in the semiconductor device of FIGS. 3A, 3B, 3C, and 3D, according to some examples.

FIG. 4 is a flowchart of a method for fabrication of a semiconductor device, according to some examples.

FIGS. 5A, 5B, 5C, 5D and 5E are cross-sectional views of a semiconductor device during various semiconductor fabrication processing steps, according to some examples.

FIG. 5F is a plot of an ion profile in the semiconductor device of FIGS. 5A, 5B, 5C, 5D and 5E according to some examples.

FIGS. 6A, 6B, 6C, 6D and 6E are cross-sectional views of a semiconductor device during various semiconductor processing fabrication steps, according to some examples.

FIGS. 7A, 7B, 7C, 7D, 7E and 7F are cross-sectional views of a semiconductor device during various semiconductor processing fabrication steps, according to some examples.

FIGS. 7G and 7H are cross-sectional views of a semiconductor device during various semiconductor processing fabrication steps, according to some examples.

FIGS. 7I and 7J are cross-sectional views of a semiconductor device during various semiconductor processing fabrication steps, according to some examples.

FIGS. 8A and 8B are cross-sectional views of a semiconductor device during various semiconductor fabrication processing steps, according to some examples.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The FIGS. are drawn to clearly illustrate the relevant elements or features and are not necessarily drawn to scale.

### DETAILED DESCRIPTION

Aspects of the present disclosure relate to a semiconductor device. In one example, the semiconductor device is a field-effect transistor (FET) that includes, in part, a semiconductor layer, a barrier layer on the semiconductor layer, a gate layer on the barrier layer, and a dielectric layer on the gate layer. At least one of the barrier layer, the gate layer or the dielectric layer may have a carbon concentration of 1×10¹⁶ cm⁻³ or less.

In another example, a semiconductor device includes, in part, a semiconductor layer with opposing first and second surfaces. The semiconductor layer may include, in part, an isolation region and an active region. The semiconductor device may further include, in part, a barrier layer on the first surface of the semiconductor layer. The isolation region extends into the barrier layer. The isolation region may include ions. The concentration of the ions within the isolation region may peak at a depth below a surface of the barrier layer and drop from the depth towards the surface. The concentration of the ions at the surface may be at least 10% of the concentration of the ions at the depth. The semiconductor device may further include, in part, a gate layer on the barrier layer and in the active region, and a dielectric layer on the gate layer.

In another example, a semiconductor device may include, in part, a semiconductor layer including an isolation region and an active region, a barrier layer on the semiconductor layer, a gate layer on the barrier layer and in the active region, and a dielectric layer on the gate layer. The isolation region extends into a first portion of the dielectric layer. A second portion of the dielectric layer over the active region has different chemical compositions from the first portion.

In another example, a method includes, in part, forming a gate layer on a barrier layer and a semiconductor layer, forming a dielectric layer on the gate layer, forming a photoresist layer on the dielectric layer and in which the dielectric layer separates the gate layer from the photoresist layer, patterning the photoresist layer, performing an ion implantation operation on parts of the barrier layer and the semiconductor layer under the patterned the photoresist layer, and removing the patterned photoresist layer.

A GaN-based field-effect transistor, such as a GaN-based HEMT, may include a heterojunction formed by a channel layer (e.g., a GaN layer) and a barrier layer (e.g., an aluminum gallium nitride (AlGaN) layer). A high-density two-dimensional electron gas (2DEG) region may be formed at the heterojunction to operate as the transistor channel. For example, the 2DEG layer may have a sheet charge density greater than about 1.0×10¹³ cm⁻², and thus can have a low static on-state resistance. GaN-based HEMTs are suitable for use in high frequency and high power applications due to, for example, their high breakdown field, high electron mobility, low static resistance, and high thermal conductivity.

Some GaN-based HEMTs are formed using semiconductor processing steps that cause carbon atoms to penetrate the channel layer of the HEMTs. Carbon atoms form deep acceptor sites and trap electrons, in turn, causing the electron current flow in the channel to collapse. As described herein, a FET, such as a GaN-based HEMT, is formed using processing steps that inhibit the transfer of carbon atoms onto the surface close to the channel of the FET, thereby preventing the drain current collapse.

Various features are described hereinafter with reference to the FIGS. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some FIGS. for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications, or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may be directed to group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2DEG at the heterojunction interface.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

GaN-based HEMTs include heterostructures that may induce two-dimensional electron gas (2DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer near the interface of the heterostructure to form a conductive channel in the GaN layer (which is thus referred to as the channel layer). Compared to silicon-based transistors, GaN-based transistors generally have high breakdown electric field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement mode high electron mobility transistor (e-HEMT) or a depletion mode high electron mobility transistor (d-HEMT). For example, the gate structure of an e-HEMT may include a p-type GaN (p-GaN) layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2DEG channel under the p-GaN gate structure, such that the conductive path between the source and drain may be disabled and thus the e-HEMT may be turned off when no gate drive voltage is applied to the gate electrical contact. When a positive voltage above the gate threshold voltage is applied to the gate electrical contact, the gate structure may attract electrons such that the 2DEG under the gate structure may be replete with electrons, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2DEG under the gate structure may not be depleted such that the conductive path in the channel layer between the drain structure and the source structure may be enabled even without a positive gate voltage. A d-HEMT can be turned off by applying a negative gate voltage to the gate electrical contact to deplete electrons from the 2DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

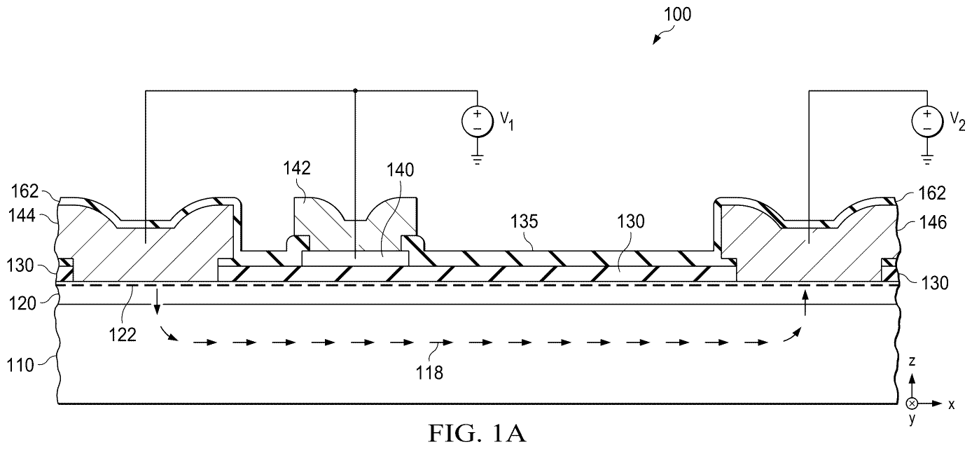

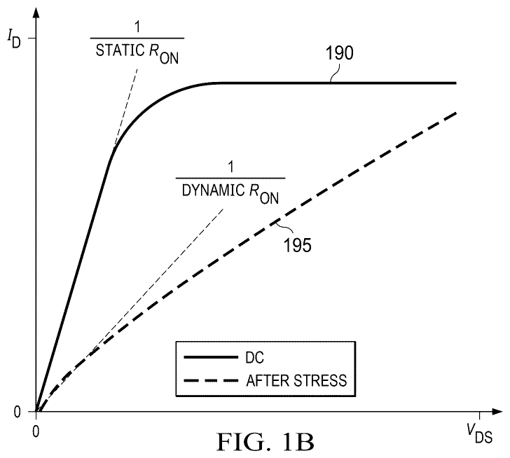

FIG. 1A is a cross-sectional view of an example of a high electron mobility transistor (HEMT) 100 under an operation condition where a voltage V₁ is applied to the gate structure 140 and source structure 144 relative to the body 120 of the transistor, and a voltage V₂ is applied to the drain structure 146 relative to the body of the transistor. The voltages V₁ and V₂ may depend on the operation condition (e.g., whether the transistor is on or off) of HEMT 100. In a condition where HEMT 100 is on, and source voltage V₁ is lower than the drain voltage V₂, electron can flow from the source structure to the drain structure within the 2DEG region 182 of the transistor along direction 118.

As is described in detail below, HEMT 100 can be formed using a semiconductor processing technique that causes carbon atoms of carbon-rich organic photoresist to be transferred from a photoresist to the channel layer 120 of the transistor. Carbon atoms form deep acceptor sites and therefore trap electrons when the channel layer includes, for example, a GaN layer. The trapping of the electrons, in turn, causes the electron current flow along direction 118 between the source and drain structures of the transistors to collapse. Because carbon atoms have a relatively high activation energy of nearly 900 milli-electron volts (meV), electrons trapped by the carbon atoms have a relatively long time constants and thus may remain trapped for a period that can last from seconds to days.

FIG. 1B shows the drain-to-source current (I_{DS}) as a function of drain-to-source voltage (V_{DS}) of transistor 100 under static and stressed bias conditions. During a static bias condition, shown in FIG. 1B as plot 190 of I_{DS}-vs-V_{DS}, when there are no trapped electrons, the transistor has a high conductance, represented by the reciprocal of static on-resistance,

$$\frac{1}{Static {R}_{ON}} ,$$

as shown by the slope of plot 190 near the origin of the axes. After the transistor is stressed due to high biasing and trapping of the electrons, the current collapses and the I_{DS}-vs-V_{DS} plot changes to that shown 195, according to which the conductance of the transistor falls to a value represented by the reciprocal of dynamic on-resistance,

$$\frac{1}{Dynamic {R}_{ON}} ,$$

defined by the slope of plot 195 near the origin of the axes.

Referring to FIG. 1A, HEMT 100 is an enhancement mode (e-mode) GaN-based transistor that includes, in part, a substrate 110, a channel layer 120, a barrier layer 130, a gate structure 140, a source structure 144, and a drain structure 146. Substrate 110 may include, for example, a silicon substrate, a silicon carbide substrate, a semiconductor-on-insulator (SOI) substrate, a sapphire substrate, a gallium nitride (GaN) substrate, a gallium arsenide (GaAs) substrate, an engineered GaN substrate (a Qromis™ Substrate Technology (QST) substrate), a substrate including another semiconductor material that has a bandgap wider than the bandgap of silicon, or any other suitable substrate. In one example, substrate 110 may include a bulk silicon substrate, and may also include one or more transition layers or buffer layers of suitable materials for accommodating the lattice mismatch between substrate 110 and channel layer 120 (e.g., to reduce or minimize lattice defect generation and/or propagation in channel layer 120). For example, the transition layers or buffer layers may have a gradient concentration of one or more elements in a surface normal direction (e.g., z direction) of substrate 110 to gradually change the lattice constant.

Channel layer 120 and barrier layer 130 may be epitaxially grown on substrate 110 to form a heterostructure that may induce a 2DEG layer 122 near the interface between channel layer 120 and barrier layer 130 due to the different energy band structures of channel layer 120 and barrier layer 130. The 2DEG layer 122 may conduct current in a two-dimensional plane (e.g., an x-y plane). In some examples, channel layer 120 may be a portion of substrate 110. Channel layer 120 may include, for example, a gallium nitride (GaN) layer, an aluminum gallium nitride (AlGaN) layer, or an indium aluminum nitride (InAlN) layer. In some examples, the material of channel layer 120 may include a doped material, such as a material doped by diffusion of dopants from another layer, or includes an intrinsic material. Barrier layer 130 may include, for example, an AlGaN layer. Other materials may also be used for channel layer 120 and barrier layer 130. For example, channel layer 120 may include indium aluminum gallium nitride (InᵢAlⱼGa₁₋ᵢ₋ⱼN) (where 0≤i≤1, 0≤j≤1, and 0≤i+j≤1), and barrier layer 130 may include indium aluminum gallium nitride (InₖAl_{f}Ga₁₋ₖ₋ₗN) (where 0≤k≤1, 0≤l≤1, and 0≤k+l≤1).

The gate structure of HEMT 100 may include a gate semiconductor layer 140 over an upper surface of barrier layer 130. In some examples, gate semiconductor layer 140 may include a p-doped semiconductor layer. For example, gate semiconductor layer 140 may include a GaN layer, or more generally, an InₘAlₙGa₁₋ₘ₋ₙN layer (where 0≤m<1, 0≤n<1, and 0≤m+n≤1). The p-type dopants for doping gate semiconductor layer 140 may include magnesium (Mg), carbon (C), zinc (Zn), and the like, or a combination thereof. In examples where gate semiconductor layer 140 includes GaN doped with a p-type dopant, gate semiconductor layer 140 may be referred to as a p-GaN layer. In some examples, a concentration of the dopant that is electrically activated in gate semiconductor layer 140 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 140 may be formed by epitaxial growth and selective etching using an etch mask, or may be formed by selective area growth using a growth mask. The etch mask or growth mask may define the shape and size of gate semiconductor layer 140. The doping density and the thickness of p-doped gate semiconductor layer 140 and the thickness of barrier layer 130 under gate semiconductor layer 140 may be selected such that the p-doped gate semiconductor layer 140 may deplete 2DEG 122 under gate semiconductor layer 140, such that HEMT 100 is turned off without a positive gate voltage and may be turned on by applying a positive voltage to the gate structure.

A gate electrical contact 142 may be formed on gate semiconductor layer 140 to apply a gate voltage to gate semiconductor layer 140. Gate electrical contact 142 may be electrically coupled to a gate drive circuit through electrical interconnects such as conductive traces and/or vias (now shown). In some examples, gate electrical contact 142 may laterally extend beyond gate semiconductor layer 140 to form a gate field plate, for example, to reduce current collapse and dynamic on-state resistance, and increase the breakdown voltage. Gate electrical contact 142 may include one or more metal and/or metal alloy materials having high electrical conductivity.

At the source region of HEMT 100, a source electrical contact 144 may extend through barrier layer 130 and contact a source region of channel layer 120. Source electrical contact 144 may include a metal or metal alloy and may form a low-barrier metal-to-semiconductor contact (e.g., an ohmic contact) with channel layer 120. In some examples, source electrical contact 144 may not extend through barrier layer 130 and may be electrically coupled to the source region of channel layer 120 through, for example, tunneling effects. In some examples, one or more source field plates may be formed and may be coupled to source electrical contact 144. The source field plates may be used to reduce current collapse and dynamic on-state resistance and/or increase the breakdown voltage of HEMT 100.

At the drain region of HEMT 100, a drain electrical contact 146 may extend through barrier layer 130 and contact a drain region of channel layer 120. Drain electrical contact 146 may include a metal or metal alloy and may form a low-barrier metal-to-semiconductor contact (e.g., an ohmic contact) with channel layer 120. In some examples, drain electrical contact 146 may not extend through barrier layer 130 and may be electrically coupled to the source region of channel layer 120 through, for example, tunneling effects.

Each of gate electrical contact 142, source electrical contact 144, and drain electrical contact 146 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or a combination thereof. In some examples, the alloy may include, for example, titanium tungsten aluminum (TiWAl) or titanium aluminum nitride (TiAlN), or a combination thereof.

In some examples, HEMT 100 may include one or more dielectric layers 162 that isolate and protect the gate structure, drain structure, and source structure. The one or more dielectric layers may include a same dielectric material or different dielectric materials deposited in one or more deposition processes. For example, the one or more dielectric layers may include an oxide-based material or a nitride-based material, such as silicon oxide (e.g., a phosphosilicate glass (PSG)), aluminum oxide, silicon nitride, and the like. In some examples, the one or more dielectric layers may further include one or more etch stop layers, such as silicon nitride (SiN) and the like, for controlling the etch depth of etching processes (e.g., for patterning a dielectric or metal layer).

In some examples, the electrical contacts or other metal electrical interconnects in HEMT 100 may each include one or more metal barrier layers and/or one or more adhesion layers (e.g., titanium nitride (TiN), tantalum nitride (TaN), and the like, or a combination thereof) between the metal material (e.g., Al, Cu, W, and the like, or a combination thereof) and the one or more dielectric layers. The one or more metal barrier layers may prevent the diffusion of metal atoms into the one or more dielectric layers. The one or more adhesion layers may be used to improve the adhesion of the metal material to the dielectric material of the one or more dielectric layers to reduce or avoid defects and reliability issues such as interfacial delamination.

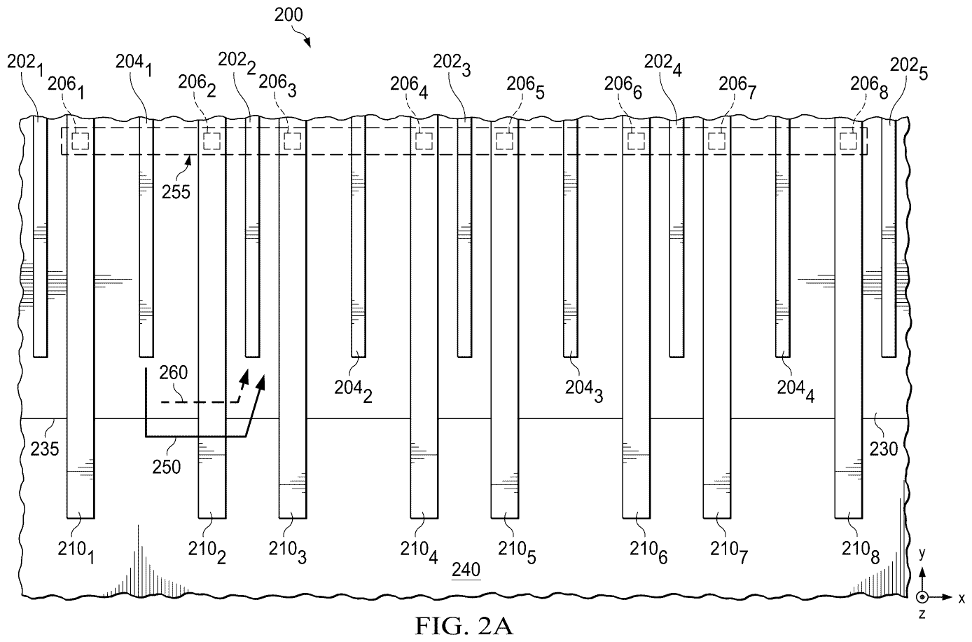

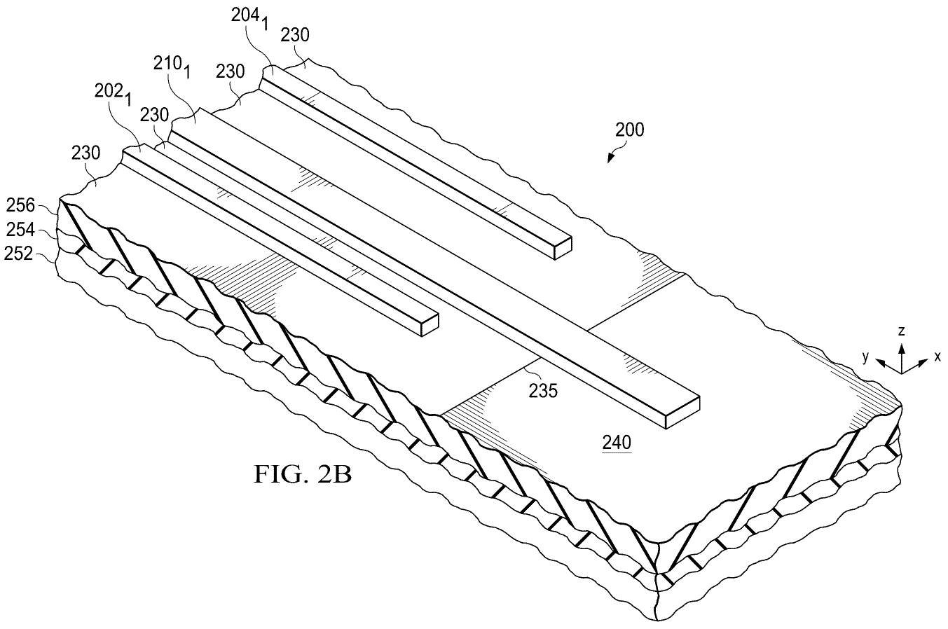

FIG. 2A is a plan view of a semiconductor device 200 according to some examples. Semiconductor device 200, which in this example is a FET, is shown as including, in part, a multitude of parallel gate structures (alternatively referred to herein as gate fingers, or gates), 8 of which, namely 210₁, 210₂ . . . 210₈ are shown in FIG. 2A. Positioned along opposing sides of each gate fingers 210; (i is an index ranging from 1 to 8 in this example) are a source contact—coupled to a source region of the FET—and a drain contact coupled to a drain region of the FET. For example, source contact 202₁ is shown as being positioned to the left of gate finger 210₁, and drain contact 204₁ is shown as being positioned to the right of gate finger 210₁. In a similar manner, source contact 202₃ is shown as being positioned to the left of gate finger 210₅, and drain contact 204₃ is shown as being positioned to the right of gate finger 210₅. Gate fingers 210; are connected to one another via metal interconnect 250 and gate contacts 206ᵢ. Although not shown in FIG. 2A, it is understood that the source contacts are connected to one another via a metal interconnect, and drain contacts are connected to one another via another metal interconnect.

Boundary line 235 is defined by a patterned mask (e.g., a patterned photoresist) separating active region 230 of FET 200 from isolation region 240 of FET 200. Isolation region 240 includes implanted impurities in order to inhibit the formation of a 2DEG region due to, for example, the damage imparted to the semiconductor crystal (e.g., GaN crystal) during the ion implantation. Current flow in the isolation region is therefore inhibited. In some examples, the ion dosage to be implanted can be in the range of 10¹¹-10¹⁸ cm⁻², and there can be 50%-100% of the ion dosage remaining in the isolation region. Also, the isolation boundary can have a width due to, for example, the scattering and straggling of the ions with the semiconductor crystal. In some examples, the isolation boundary can have a width of 10-1000 nanometers (nm).

If the gate fingers terminate within the active region 230 and do not extend into the isolation region 240 (not shown in FIG. 2A) so as to avoid the dual subthreshold voltages associated with FET 200, during the normal mode of operation when the transistor is switching, current crowding may occur near the edges of source/drain contacts facing the boundary of the isolation region, which in turn, may adversely affect operational safety of the transistor.

To mitigate the current crowding effect and avoid damage to the transistor, gate fingers may extend into the isolation region. In some examples, the gate fingers may extend into the isolation region by, for example, 0.1-10 micrometers (um). By extending the gate fingers into the isolation region, FET 200 may have two subthreshold voltages, one of which is caused by gate fingers 210ᵢ extending into the isolation region, where a current path 250 can be enabled between the source and drain contacts through isolation region 240. The other subthreshold voltage is intrinsic to the transistor and is defined by, for example, the characteristics of the active region, gate length, and the like, where a current path 260 can be enabled between the source and drain contacts through active region 230. Therefore, by extending the gate fingers into the isolation region, a tradeoff is made between mitigating the current crowding effect and the dual subthreshold voltage characteristics of the transistor.

FIG. 2B is a perspective view of FET 200 of FIG. 2A, according to one example. FET 200 is shown as having a vertical stack (e.g., stacked along the z-axis of FIG. 2A) of layers including, in part, a substrate 252, a buffer layer 254 above substrate 252, and a barrier layer 256 above buffer layer 254. For simplicity, only one of the gate fingers, namely gate finger 210₁, only one source contact 202₁, and only one drain contact 204₁ of FET 200 are shown in FIG. 2B. As was also described with reference to FIG. 2A, boundary line 235 is defined by a patterned mask that separates isolation region 240 from active region 230.

Referring to FIGS. 2A and 2B, in various examples, substrate 252 may include, for example, a silicon substrate, a silicon carbide substrate, an SOI substrate, a sapphire substrate, a GaN substrate, a GaAs substrate, an engineered GaN substrate (a QST substrate), a substrate including another semiconductor material that has a bandgap wider than the bandgap of silicon, or any other suitable substrate. In some examples, buffer layer 254 may include GaN, and barrier layer 256 may include AlGaN. In some examples, the gate fingers include p-type GaN (p-GaN). In some examples, the thickness of AlGaN barrier layer in the isolation region 240 is greater than the thickness of AlGaN barrier in the active layer 230. In some examples, the thickness of the GaN buffer layer over the active region is greater than the thickness of the GaN buffer layer over the isolation region. The drain/source contacts and the gate metal positioned over the p-GaN gate fingers may include titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or any combinations thereof. In some examples, the alloy may include, for example, titanium tungsten aluminum (TiWAl), titanium aluminum nitride (TiAlN), or a combination thereof.

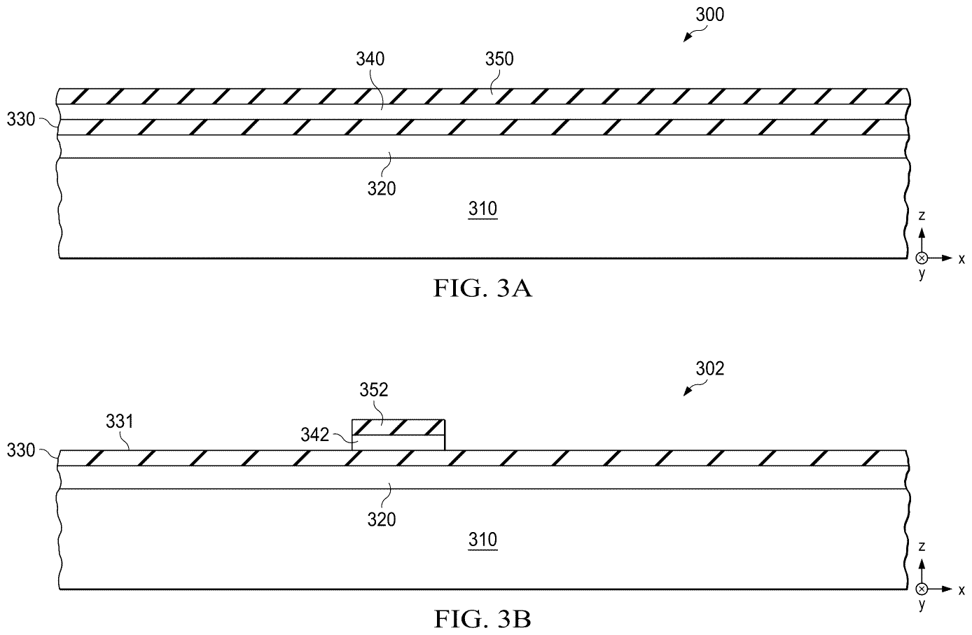

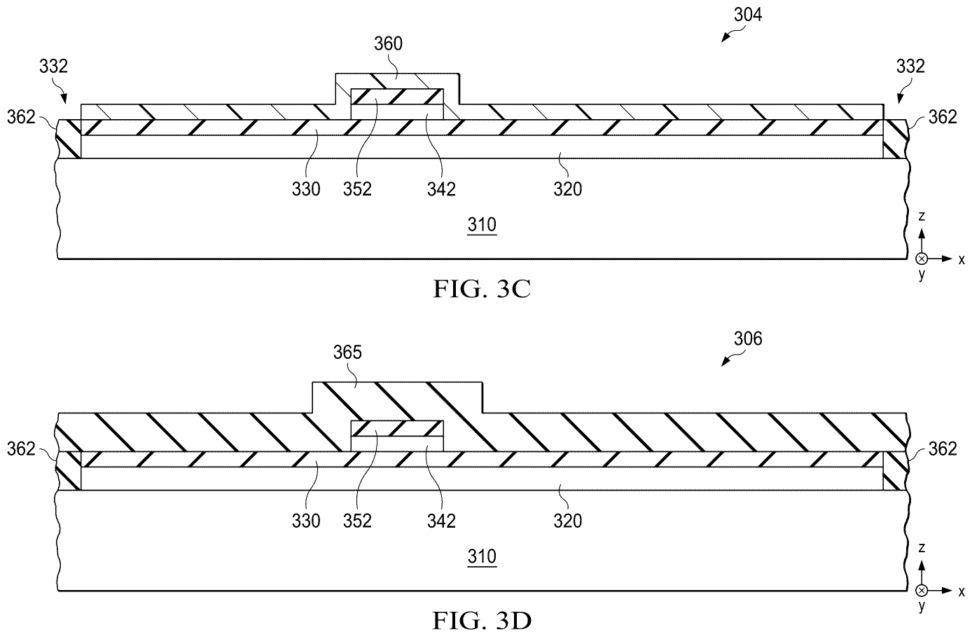

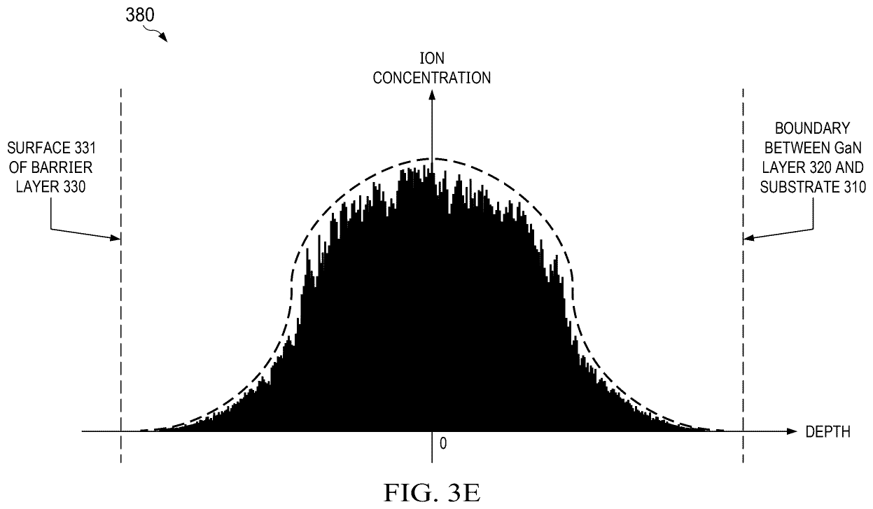

FIG. 3A is a cross-sectional view of a semiconductor structure 300 after performing a number of semiconductor processing steps according to some examples. Semiconductor structure 300 is shown as including a substrate 310, a channel layer 320, a barrier layer 330, a gate semiconductor layer 340, and a cap layer 350. Substrate 310 may include a bulk silicon substrate, and may also include one or more transition layers or buffer layers of suitable materials for accommodating the lattice mismatch between substrate 310 and channel layer 320. Channel layer 320 and barrier layer 330 may be epitaxially grown on substrate 310 to form a heterostructure that may induce a 2DEG layer near the interface between channel layer 320 and barrier layer 330 due to the different energy band structures of channel layer 320 and barrier layer 330. Channel layer 320 may include, for example, a GaN layer. Barrier layer 330 may include, for example, an AlGaN layer. Gate semiconductor layer 340 may include a p-type GaN layer, also referred to herein as p-GaN layer. Cap layer 150 may include, for example, a Silicon Nitride (SiN) layer that is deposited to protect the surface of gate semiconductor layer 340.

FIG. 3B shows the cross-sectional view of the semiconductor structure of FIG. 3A after performing masking, patterning and etching operations to define gate structure 342 and cap structure 352. The gate structure 342 and cap structure 352 are shown as having the same footprint in this example. In one example, a dry etch process may be used to form gate structure 342 and cap structure 352, and a surface 331 of barrier layer 330 is exposed.

To form the isolation regions, as described above with reference to FIGS. 2A and 2B, a layer of photoresist 360 is deposited on the surface of semiconductor structure 302 of FIG. 3B, including surface 331, to cover the sidewalls of gate structure 342, and the surface of cap structure 352 and barrier layer 330. The photoresist is then patterned (e.g., by photolithography) to form openings 332. Next, using an ion implantation step, ions, such as ions of argon, fluorine, nitrogen, boron, phosphorus, indium, arsenide, antimony, oxygen, hydrogen, carbon, etc. are implanted to form isolation regions 362 via openings 332, as shown in FIG. 3C. Alternatively, after using a dry etch process, a mesa may be formed in the isolation regions. Portions of the channel region 320 that are not in the isolation regions 362, are active regions.

FIG. 3E illustrates a plot 380 of ion concentration in isolation region 362 with respect to a depth that is orthogonal to surface 331 (e.g., along the z-axis in FIGS. 3A-3D). Plot 380 shows a solid line representing the concentration with fluctuations, and a dotted line representing a smoothed version of the solid line, which represents a trend line of the concentration. In plot 380, the depth zero can represent a target depth of the ion implantation below surface 331 and in (formerly) channel region 320. As shown, after the ion implantation, due to scattering and/or diffusion, a concentration profile of ions centered at depth zero is formed. The concentration of the ions can peak at the depth zero, and the trendline (represented by the dotted line) can roll off towards the negative direction (e.g., towards surface 331) and the positive direction (e.g., away from surface 331 and towards substrate 310. The concentration of the ions can reach zero below surface 331 and above substrate 310. In some examples, the roll off rates on both sides of depth zero can be the same (or at least similar), giving rise to a symmetrical concentration profile.

Referring back to FIG. 3D, after forming isolation regions 362, photoresist layer 360 is removed and a passivation layer 365 is deposited to form the semiconductor structure 306. Passivation layer 365 may include a dielectric layer and may include, for example, a SiN layer, an aluminum nitride (AlN) layer, an aluminum oxide (Al₂O₃) layer, an aluminum oxide nitride (AlON) layer, etc. Next, using patenting and etching steps, a portion of the SiN of both the cap layer and the passivation layer is removed (not shown) to open a window and expose the surface of gate layer structure 342. Thereafter, a layer of metal is deposited (not shown) above gate layer structure 342 to form an ohmic contact therewith.

Referring to FIG. 3C, photoresist layer 360 is a rich source of carbon atoms that can diffuse into the channel layer 320 (e.g., AlGaN layer) and p-GaN structure 342. The carbon atoms can form deep acceptor sites and trap electrons in the channel layer. In such cases, the concentration of carbon atoms in each of channel layer 320 and p-GaN structure 342 can be several orders over 1×10¹⁶ cm⁻³, and may cause an electron current flow between the source and drain regions of the transistor to collapse. Moreover, the surface of AlGaN layer and the sidewalls of the p-GaN layer may be damaged and get oxidized after removal of the photoresist and subsequent exposure of the surface of AlGaN layer and p-GaN sidewalls to Oxygen that is present in the air. In accordance with examples of the present disclosure, the above shortcomings are overcome by protecting the AlGaN surface and p-GaN sidewalls from carbon atoms present in the photoresist, and further protect the AlGaN surface and p-GaN sidewalls from potential damage and oxidation, as described in detail below.

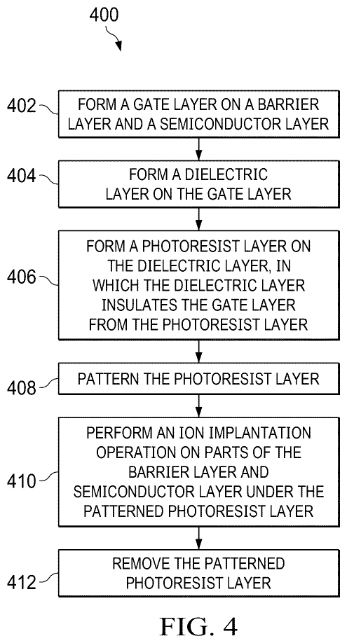

FIG. 4 is a flowchart 400 of a method associated with forming a semiconductor device, in accordance with some examples. At 402, a gate layer is formed on a barrier layer and a semiconductor layer (e.g., a channel layer). At 404 a dielectric layer is formed on the gate layer. At 406, a photoresist layer is formed on the dielectric layer as a mask for the subsequent ion implantation process, and is patterned (e.g., by photolithography) at 408. The dielectric layer insulates the gate layer from the photoresist layer. At 410, an ion implantation operation is performed on parts of the barrier layer and semiconductor layer under the patterned photoresist layer. At 412, the patterned photoresist layer is removed.

In some examples, not shown in FIG. 4, the dielectric layer is a first dielectric layer. In such examples, after removing the photoresist, the first dielectric layer and the gate layer are patterned. Thereafter, a second dielectric layer is formed on the patterned first dielectric layer, the patterned gate layer, and the isolation region.

In other examples, not shown in FIG. 4, a second dielectric layer is formed after patterning the first dielectric layer and the gate layer. In such examples, an ion implantation is performed on a part of the second dielectric layer.

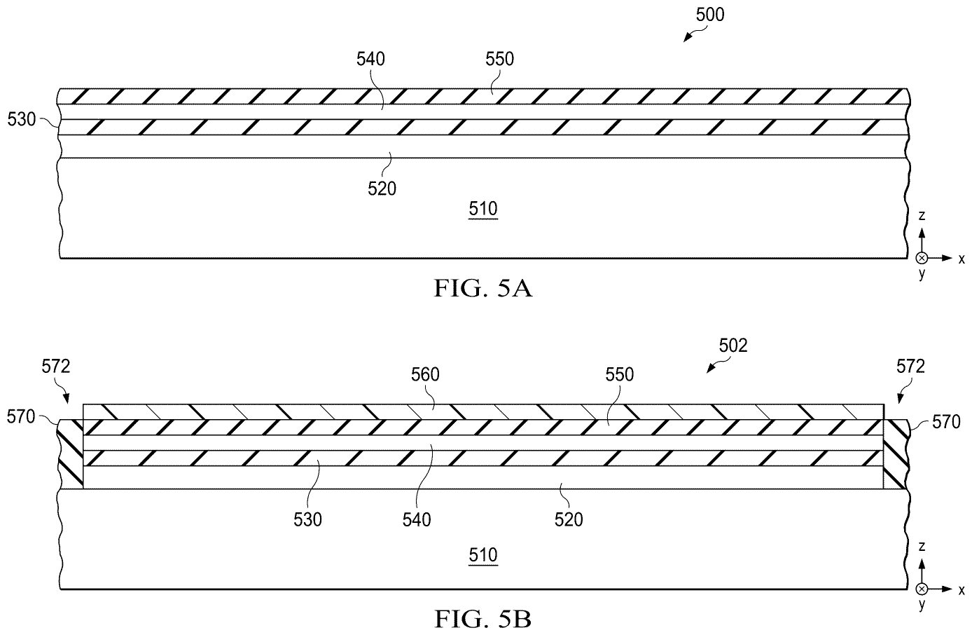

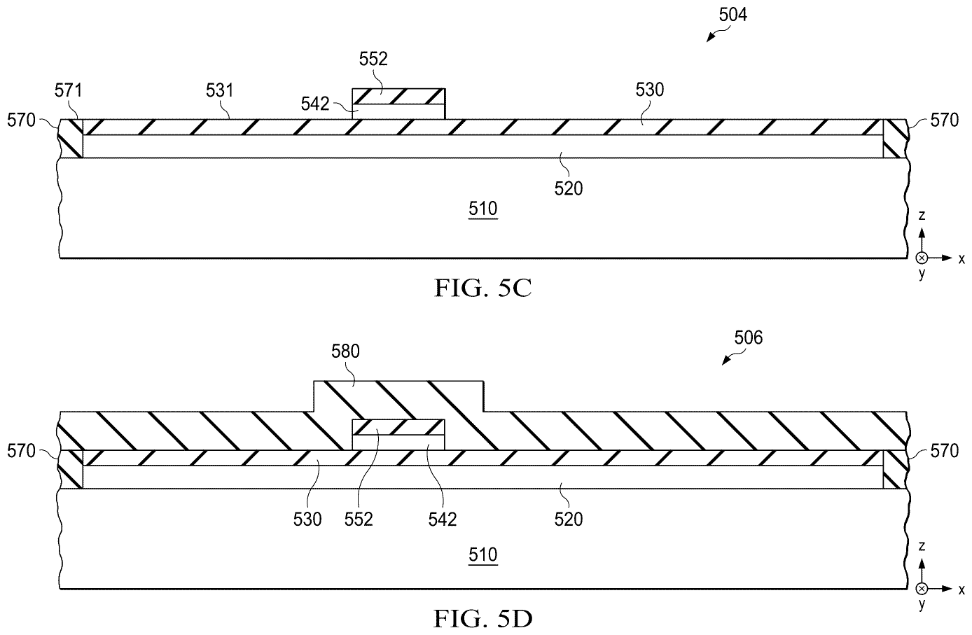

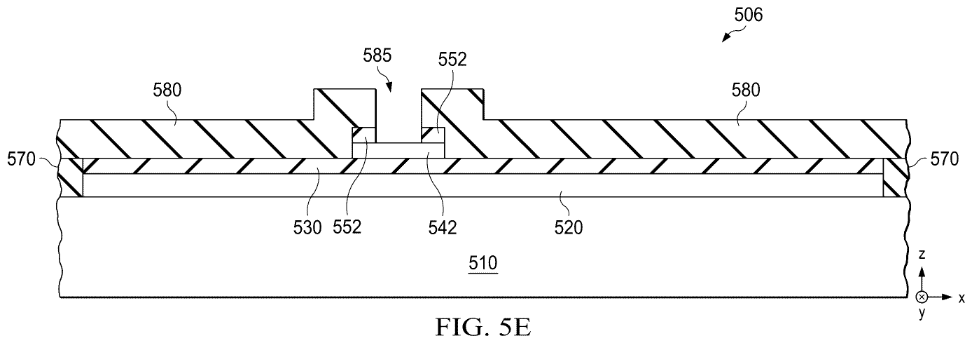

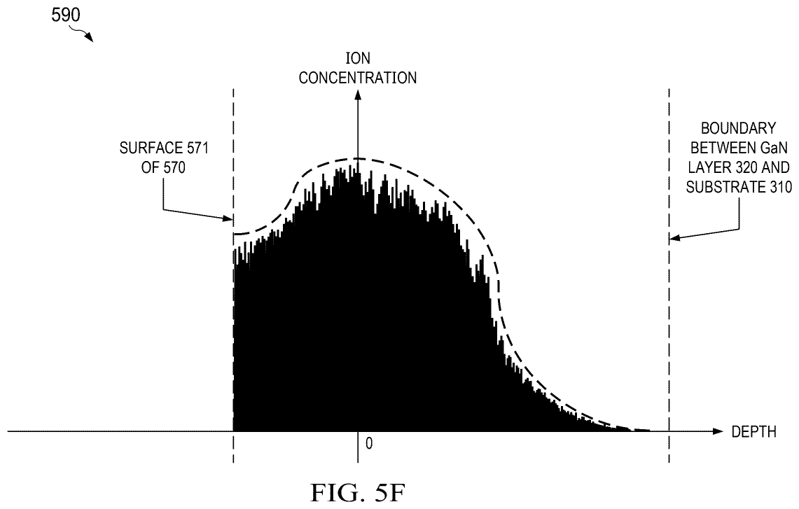

FIGS. 5A-5E are cross-sectional views of a semiconductor structure after performing a number of semiconductor fabrication processing operations to form a FET, according to some examples. Semiconductor structure 500 of FIG. 5A is shown as including a substrate 510, a channel layer 520, a barrier layer 530, a gate semiconductor layer 540, and a cap layer 550. Substrate layer 510 may include a bulk silicon substrate, and may also include one or more transition layers or buffer layers of suitable materials for accommodating the lattice mismatch between substrate 510 and channel layer 520. Channel layer 520 and barrier layer 530 may be epitaxially grown on substrate 510 to form a heterostructure that may induce a 2DEG layer near the interface between channel layer 520 and barrier layer 530 due to the different energy band structures of channel layer 520 and barrier layer 530. Channel layer 520 may include, for example, a GaN layer and is alternatively referred to hereinafter as the GaN layer. Barrier layer 530 may include, for example, an AlGaN layer and is alternatively referred to hereinafter as the AlGaN layer. Gate semiconductor layer 540 may include a p-GaN layer, and is alternatively referred to hereinafter as the p-GaN layer. Cap layer 550 may include, for example, a SiN layer and is alternatively referred to hereinafter as the SiN layer.

FIG. 5B shows the semiconductor structure of FIG. 5A after a layer 560 of photoresist is deposited and patterned on cap layer 520 to form window openings 572. Thereafter, an ion implantation operation is performed to implant ions, such as ions of argon, fluorine, nitrogen, boron, phosphorus, indium, arsenide, antimony, oxygen, hydrogen, carbon, etc., into the semiconductor structure including SiN cap layer 550, p-GaN layer 540, AlGaN layer 530, and GaN layer 520 through window opening 572. The ions are shown as having been implanted in GaN layer 520, AlGaN layer 530, p-GaN layer 540 and SiN cap layer 550 through the window openings 572 to form isolation regions 570. The implanted ions damage the crystal structure of GaN layer 520. When the ions are implanted into the crystal structure of AlGaN barrier layer 530 and GaN layer 520 through SiN cap layer 550 and p-GaN layer 540, some of the ions can diffuse/scatter into SiN cap layer 550, such that an ion concentration profile is formed that extends from a target implantation location within GaN layer 520 and extends above into SiN cap layer 550 and p-GaN layer 540 and extends below and towards substrate 510. Accordingly, part of the p-GaN layer 540 in the isolation region, such as end of gate 210₁ that extends into the isolation region as shown in FIG. 2B, may also include the ions. In some examples, isolation regions 570 may be mesa structures. In such examples, isolation regions 570 may not be coplanar with barrier layer 530.

In some examples, SiN layer 550 may be patterned, using photoresist 560, to form window opening 572 through which the ions may be implanted to form isolation regions 570. In such examples, isolation regions 570 do not extend into SiN layer 550. Also, photoresist 560 may or may not be removed prior to the ion implantation operation. In examples where photoresist 560 is removed prior to the ion implantation and SiN layer 550 is used as a mask for the ion implantation, a thickness of SiN layer 550 may be chosen based on, for example, the energy of the ion implantation, so that SiN layer 550 is thick enough to block the ions.

FIG. 5C shows the semiconductor structure of FIG. 5B following a gate structure definition phase during which SiN cap layer 550 is patterned to expose p-GaN layer 540, followed by patterning of p-GaN layer 540 to form p-GaN gate structure 542 and SiN cap structure 552. As part of the patterning of SiN cap layer 550 and p-GaN layer 540, the part of isolation regions 570 formed in SiN cap layer 550 and p-GaN layer 540 (in FIG. 5B) are removed, forming a surface 571 that, in some examples, is coplanar with a surface 531 of barrier layer 530. In examples where isolation regions 570 are mesa structures, surface 571 is not coplanar with surface 531. In both cases, a discontinuous ion concentration profile with respect to depth, as explained below.

FIG. 5F illustrates a plot 590 of ion concentration in isolation region 570 with respect to a depth that is orthogonal to surface 531 (e.g., along the z-axis in FIGS. 5A-5E). Plot 590 shows a solid line representing the concentration with fluctuations, and a dotted line representing a smoothed version of the solid line, which represents a trend line of the concentration. In plot 590, the depth zero can represent a target depth of the ion implantation below surface 531 and in (formerly) channel region 520. As shown, after the ion implantation, due to scattering and/or diffusion, a concentration profile of ions centered at depth zero is formed. The concentration of the ions can peak at the depth zero, and the trend line can roll off towards the negative direction (e.g., towards surface 531) and the positive direction (e.g., away from surface 571 and towards substrate 510. The concentration of the ions can reach zero above substrate 510, but does not reach zero below surface 531, because of the removal of p-GaN layer 540 and SiN cap layer 550 (shown in FIG. 5C) that carry part of the ions. Accordingly, the ion concentration is non-zero (e.g., at least 10% of the peak concentration at the target depth of the ion implantation) at surface 571, and a discontinuity of the ion concentration profile at surface 571 results, leading to an asymmetrical concentration profile.

Thereafter, a passivation layer 580 is deposited over the semiconductor structure of FIG. 5C to form the semiconductor structure 506 shown in FIG. 5D. Passivation layer 580 can be similar to passivation layer 365 and can include a dielectric layer. The thickness of passivation layer 580 can be a function of the operation voltage of the transistor, as well as a material of passivation layer 580. For example, in a case where passivation layer 580 is a SiN layer, it may have a thickness range of 10 nanometer (nm) to 200 nm. In a case where passivation layer 580 is AlN, Al₂O₃, AlON, or some combination of AlN/Al₂O₃, it may have a thickness in the range of 1-20 nm and can be formed by an atomic layer deposition (ALD) process.

Next, as shown in FIG. 5E, using masking, patterning, and etching operations, SiN cap structure 552 and passivation layer 580 are removed from areas above p-GaN structure 542 to form window opening 585 and thereby expose the surface of p-GaN gate structure 542. Thereafter, a layer of metal contact is deposited (not shown) over the semiconductor structure and subsequently patterned to make a contact with p-GaN gate structure 542. The contact can be an ohmic contact or a Schottky contact. It is understood that the FET includes source and drain structures which are not shown in FIGS. 5A-5E.

In FIGS. 5A-5E, during the formation of the isolation region 570, the surface of AlGaN layer 530 and sidewalls of p-GaN layer 540 in the active region are prevented from coming into contact with photoresist 560 and therefore are substantially protected from carbon atoms that are present in photoresist 560. Also, passivation layer 580 is formed after removal of photoresist 560. Accordingly, in FIG. 5E, each of passivation layer 580, AlGaN layer 530, and p-GaN layer 540 can have a carbon concentration of 1×10¹⁶ cm⁻³ or less.

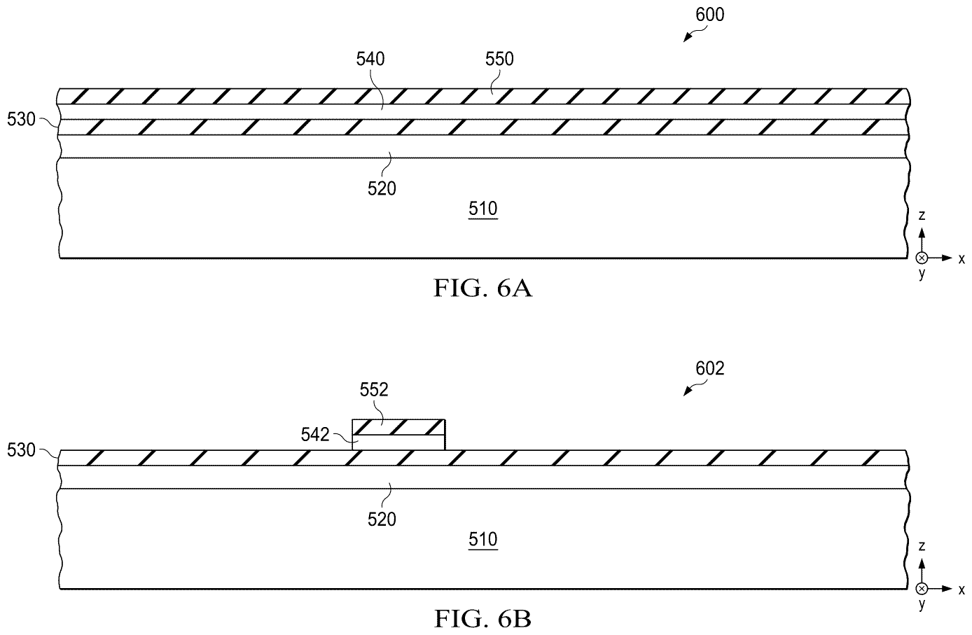

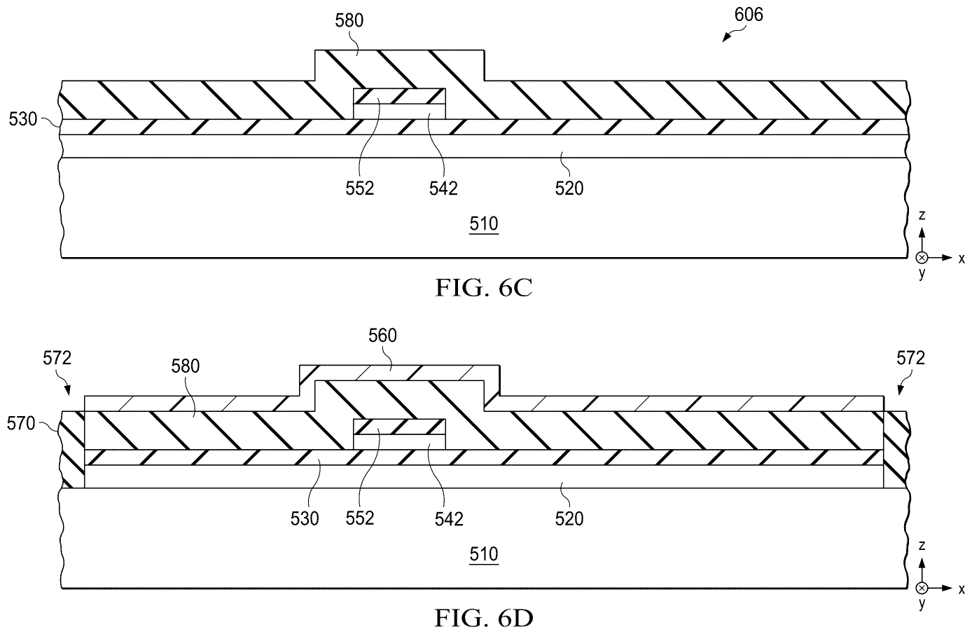

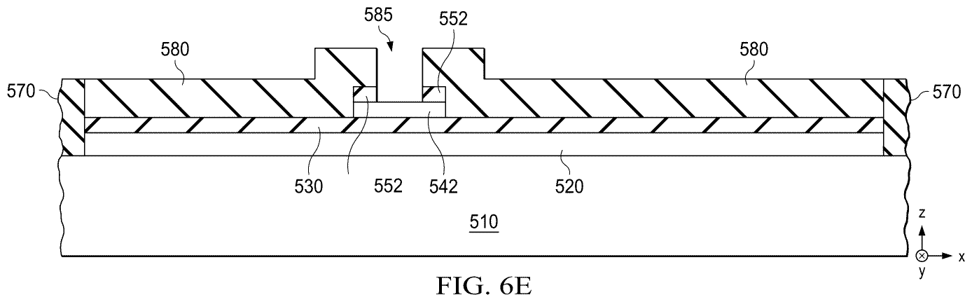

FIGS. 6A-6E are cross-sectional views of a semiconductor structure after a number of semiconductor fabrication processing operations to form a FET, according to some examples. Semiconductor structure 600 of FIG. 6A is shown as including a substrate 510, a channel layer 520, a barrier layer 530, a gate semiconductor layer 540, and a cap layer 550. Substrate layer 510 may include a bulk silicon substrate, and may also include one or more transition layers or buffer layers of suitable materials for accommodating the lattice mismatch between substrate 510 and channel layer 520. Channel layer 520 and barrier layer 530 may be epitaxially grown on substrate 510 to form a heterostructure that may induce a 2DEG layer near the interface between channel layer 520 and barrier layer 530 due to the different energy band structures of channel layer 520 and barrier layer 530. Channel layer 520 may include, for example, a GaN layer and is alternatively referred to hereinafter as the GaN layer. Barrier layer 530 may include, for example, an AlGaN layer and is alternatively referred to hereinafter as the AlGaN layer. Gate semiconductor layer 540 may include a p-GaN layer, and is alternatively referred to hereinafter as the p-GaN layer. Cap layer 550 may include, for example, a SiN layer and is alternatively referred to hereinafter as the SiN layer.

FIG. 6B shows the semiconductor structure of FIG. 6A following a gate structure definition phase during which p-GaN gate structure 542 and SiN cap structure 544 are formed using standard masking, patterning and etching steps. Thereafter, a passivation layer 580 is deposited over the semiconductor structure of FIG. 6B to form the semiconductor structure 606 shown in FIG. 6C. Next, as shown in FIG. 6D, a layer 560 of photoresist is deposited on passivation layer 580 and patterned so as to expose the surface of passivation layer 580 at window openings 572. Next, an ion implantation operation is performed using, for example, ions of argon, fluorine, nitrogen, boron, phosphorus, indium, arsenide, antimony, oxygen, hydrogen, carbon, etc., to form isolation regions 570 via openings 572. The ions propagate through passivation layer 580 and barrier layer 530 into channel layer 520 and damage the crystal structure there, thereby forming the isolation regions. Some of the ions may remain in parts of passivation layer 580 under window openings 572, such that the parts of passivation layer 580 under window openings 572 have different ions concentration (and chemical compositions) from parts of passivation layer 580 outside window openings 572 (e.g., in the active region), and the concentration of ions with respect to depth in isolation region 570 can be similar to that shown in FIG. 3E. The entire concentration profile of the ions in isolation region 570 may span (along the depth or z-axis in FIG. 6D) passivation layer 580 barrier layer 530, and channel layer 520. On the other hand, during the formation of isolation regions 570, the surface of AlGaN barrier layer 530 and sidewalls of p-GaN layer 540 in the active region are prevented from coming into contact with the photoresist, and therefore are substantially protected from carbon atoms that are present in the photoresist. Accordingly, in FIGS. 6D and 6E, each of AlGaN layer 530 and p-GaN layer 540 can have a carbon concentration of 1×10¹⁶ cm⁻³ or less. On the other hand, passivation layer 580 is in contact with photoresist 560 in FIG. 6D and may have a relatively high carbon concentration (e.g., exceeding 1×10¹⁶ cm⁻³) compared with AlGaN layer 530 and p-GaN layer 540.

Photoresist layer 560 is then removed. Subsequently, using masking, patterning and etching steps, SiN structure 552 and passivation layer 580 are removed from the areas above the p-GaN structure 524 to form window opening 585 and, thereby expose the surface of p-GaN gate structure 542, as shown in FIG. 6E. Thereafter, a contact (e.g., an ohmic contact or a Schottky contact) is formed with p-GaN gate structure 542. It is understood that the FET includes source and drain structures which are not shown in FIGS. 6A-6E. The chemical composition of the passivation layer in areas which receives implanted ions is changed.

Referring back to FIG. 6D, in some examples, passivation layer 580 can be patterned using photoresist 560 to expose barrier layer 530 and channel layer 520 in window 572, and ion implantation can be performed through window 572 to form isolation regions 570 that extends into barrier layer 530 and channel layer 520. In such examples, isolation regions 570 do not extend into passivation layer 580. In examples where photoresist 560 is removed prior to the ion implantation, passivation layer 580 can be thickened (e.g., based on the energy of the ion implantation) to be thick enough to block the ions.

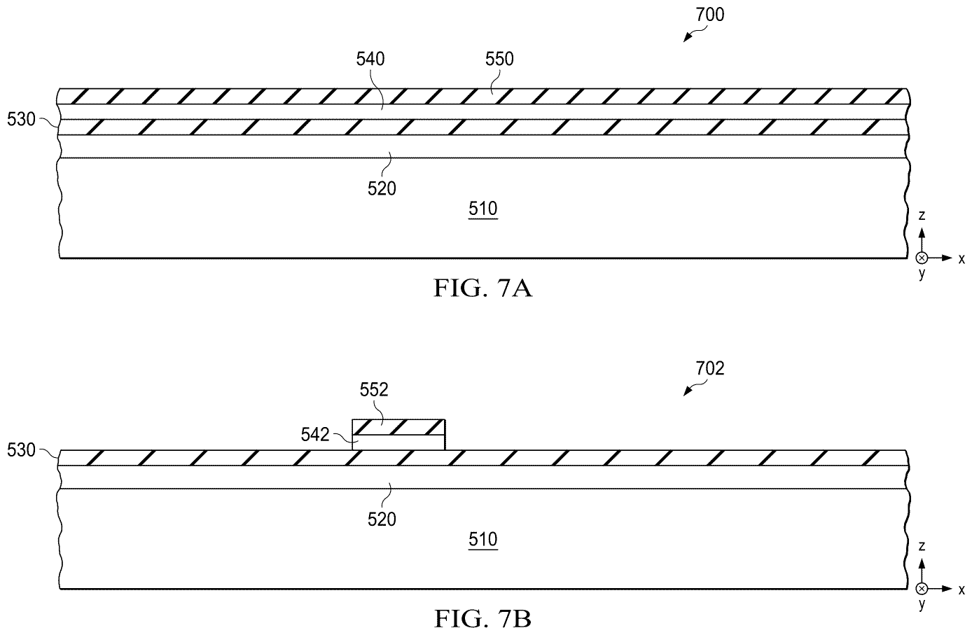

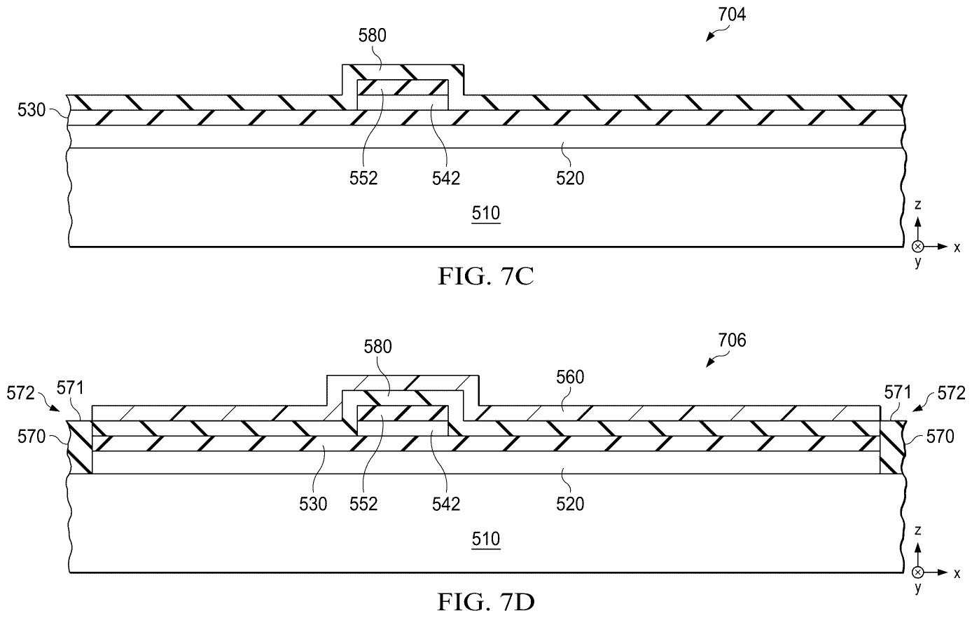

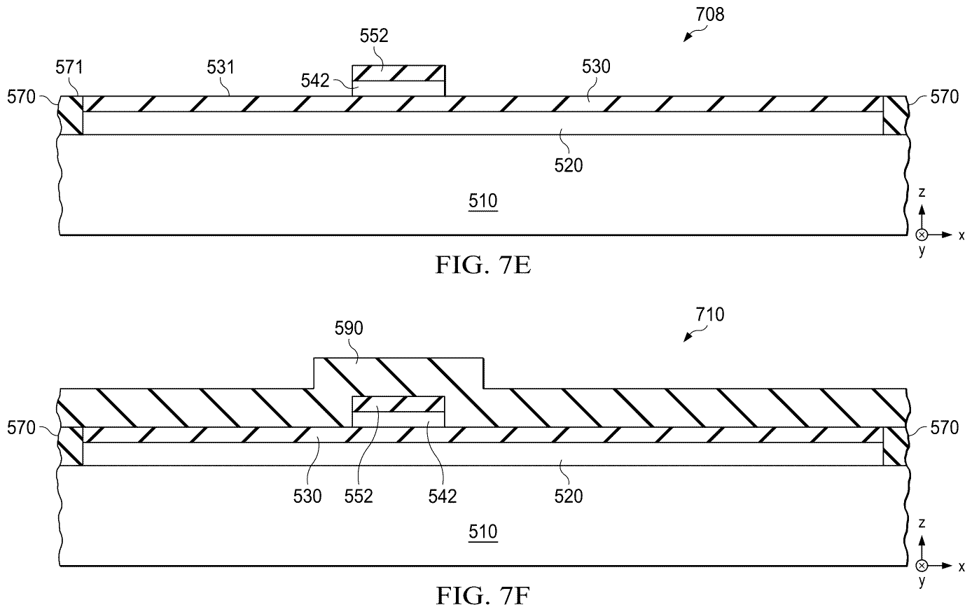

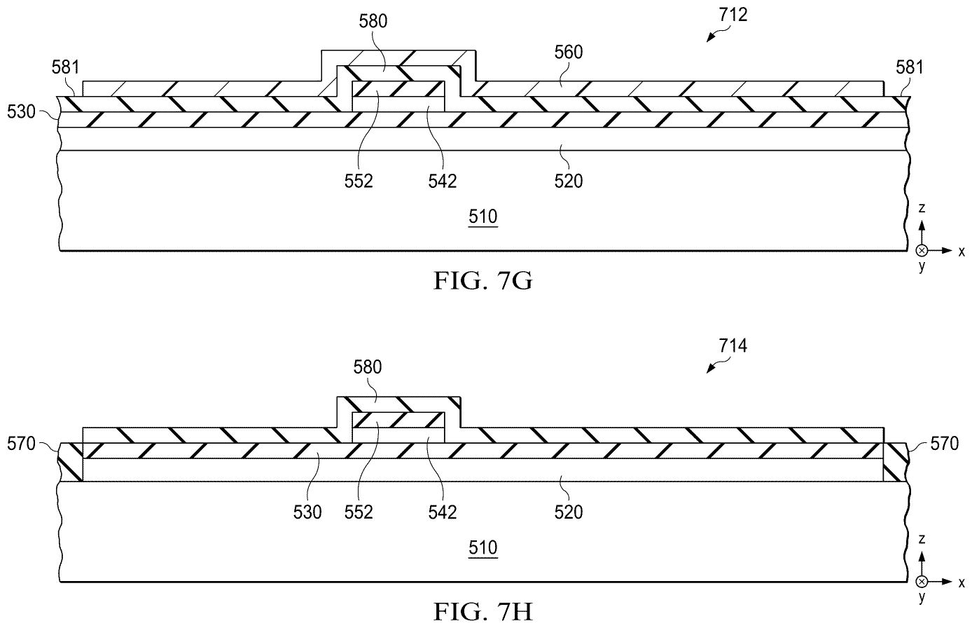

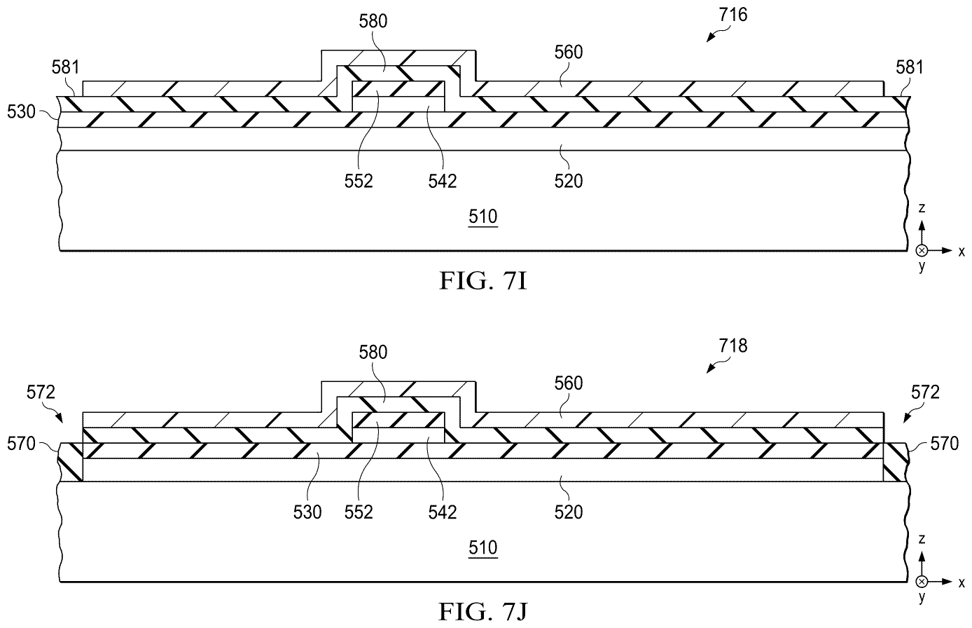

FIGS. 7A-7F are cross-sectional views of a semiconductor structure after a number of semiconductor fabrication processing operations to form a FET, according to some examples. Cross-sectional view of semiconductor structure 700 of FIG. 7A is shown as including a substrate 510, a channel layer 520, a barrier layer 530, a gate semiconductor layer 540, and a cap layer 550. Substrate layer 510 may include a bulk silicon substrate, and may also include one or more transition layers or buffer layers of suitable materials for accommodating the lattice mismatch between substrate 510 and channel layer 520. Channel layer 520 and barrier layer 530 may be epitaxially grown on substrate 510 to form a heterostructure that may induce a 2DEG layer near the interface between channel layer 520 and barrier layer 530 due to the different energy band structures of channel layer 520 and barrier layer 530. Channel layer 520 may include, for example, a GaN layer and is alternatively referred to hereinafter as the GaN layer. Barrier layer 530 may include, for example, an AlGaN layer and is alternatively referred to hereinafter as the AlGaN layer. Gate semiconductor layer 540 may include a p-GaN layer, and is alternatively referred to hereinafter as the p-GaN layer. Cap layer 550 may include, for example, a SiN layer and is alternatively referred to hereinafter as the SiN layer.

FIG. 7B shows the semiconductor structure of FIG. 7A following a gate structure definition phase during which p-GaN gate structure 542 and SiN structure 544 are formed using standard masking, patterning, and etching steps. Thereafter, as shown in FIG. 7C, a passivation layer 580 is deposited over the semiconductor structure of FIG. 7B to form the semiconductor structure 704. Subsequently, following a photoresist deposition to form photoresist 560 and patterning step to form windows 572, an ion implantation operation is performed using, for example, ions of argon, fluorine, nitrogen, boron, phosphorus, indium, arsenide, antimony, oxygen, hydrogen, carbon, etc., to form isolation regions 570 via openings 572, as shown in FIG. 7D. In the example shown in FIG. 7D, isolation regions 570 extend into passivation layer 580. In some examples, passivation layer 580 can also be patterned using photoresist 560, and isolation regions 570 do not extend into passivation layer 580. In the examples of FIGS. 7C and 7D, the thickness of passivation layer 580 can be a few nanometers (e.g., 5 nm), whereas in the examples of FIGS. 6C-6E, the thickness of passivation layer 580 can be a function of the operation voltage and can have a range of 10 nm to 200 nm.

Thereafter, photoresist layer 560 and passivation layer 580 are removed to form device structure 708 shown in FIG. 7E. The concentration of ions with respect to depth in isolation region 570 can be similar to that shown in FIG. 5F. Next, a passivation layer 590 is deposited over the semiconductor structure 708 to form device structure 710. Passivation layer 590 can be similar (in terms of material and thickness) to passivation layer 580 in the examples of FIGS. 6C-6E.

Next, a contact (e.g., an ohmic contact or a Schottky contact) is formed (not shown) above p-GaN gate structure 542 in the same manner as was described with reference to FIG. 6E. It is understood that the FET includes source and drain structures which are not shown in FIGS. 7A-7F. As shown in FIGS. 7A-7F, during the formation of the isolation regions 570, the surface of AlGaN layer 530 and the sidewalls of p-GaN layer 540 are prevented from coming into contact with photoresist 560 and therefore are substantially protected from carbon atoms that are present in photoresist 560. Also, passivation layer 590 is formed after removal of photoresist 560. Accordingly, each of AlGaN layer 530, passivation layer 590, and p-GaN layer 540 can have a carbon concentration of 1×10¹⁶ cm⁻³ or less.

In FIGS. 7A-7F, the thickness of passivation layer 580 can be reduced to reduce the energy of ion implantation and not limited by, for example, the thickness requirement of cap layer for protecting the p-GaN gate structure. Also, the portion of passivation layer 580 in isolation region 570 (and containing the ions) is removed, and a new passivation layer 590 is formed after removal of photoresist 560, therefore passivation layer 590 can be free of the implantation ions, as explained above.

In some examples, after forming the semiconductor structure 704 shown in FIG. 7C, a layer of photoresistor 560 is deposited on passivation layer 580 and subsequently patterned to expose the surface of passivation layer 580 in areas 581, as shown in FIG. 7G. After removing the passivation layer 580 in exposed areas 581, photoresist layer 560 is removed and an ion implantation operation is performed to implant ions, such as ions of argon, fluorine, nitrogen, boron, phosphorus, indium, arsenide, antimony, oxygen, hydrogen, carbon, etc., into the semiconductor structure. As shown in FIG. 7H, the ions are shown as having been implanted in GaN layer 520, and AlGaN layer 530 to form isolation regions 570. In such examples, passivation layer 580 has a relatively higher thickness to ensure the ions do not penetrate in the AlGaN layer 530.

In some examples, after forming the semiconductor structure 704 shown in FIG. 7C, a layer of photoresistor 560 is deposited on passivation layer 580 and subsequently patterned to expose the surface of passivation layer 580 in areas 581, as shown in FIG. 7I. After removing the passivation layer 580 in exposed areas 581, an ion implantation operation is performed to implant ions, such as ions of argon, fluorine, nitrogen, boron, phosphorus, indium, arsenide, antimony, oxygen, hydrogen, carbon, etc., into the semiconductor structure. As shown in FIG. 7J, the ions are shown as having been implanted in GaN layer 520, and AlGaN layer 530 to form isolation regions 570. Photo resist layer 560 is thereafter removed. Passivation layer 580 may be optionally removed after the removal of the photoresist layer or maintained.

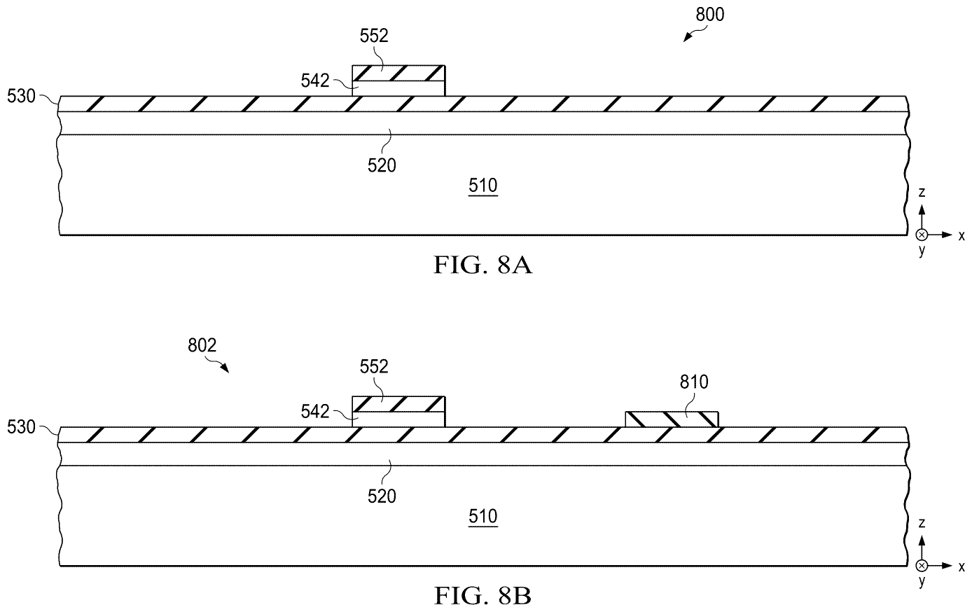

The protection of the surface of the AlGaN layer and sidewalls of the p-GaN structure as described above equally apply to depletion mode transistors, such as depletion mode p-GaN transistors. FIGS. 8A-8B are cross-sectional views of a semiconductor structure after performing a number of semiconductor fabrication processing operations associated with forming an enhancement-mode and a depletion-mode FET, according to some examples. Semiconductor device structure 800 is formed in a manner similar to the semiconductor device structure 602 described above with reference to FIG. 6B.

FIG. 8B shows the semiconductor device structure of FIG. 8A after a layer of gate oxide 810 is formed on the AlGaN layer 530, defining the gate oxide of the depletion-mode transistor. Gate oxide layer 810 may be an Aluminum oxide layer deposited and patterned, using masking and patterning steps. Thereafter, a passivation layer is deposited over the semiconductor structure 802, and isolation regions are formed in the same manner as was described above with references to FIGS. 6C and 6D. Ohmic or Schottky contacts are subsequently made to p-GaN gate structure 542, which is the gate of the enhancement-mode transistors, as well as to gate dielectric layer 810 to form the gate of the depletion-mode transistors.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A semiconductor device comprising:
a semiconductor layer;
a barrier layer on the semiconductor layer;
a gate layer on the barrier layer; and
a dielectric layer on the gate layer, in which at least one of the barrier layer, the gate layer, or the dielectric layer has a carbon concentration of 1×10¹⁶ cm⁻³ or less.

2. The semiconductor device of claim 1, wherein the dielectric layer has a same footprint as the gate layer.

3. The semiconductor device of claim 1, wherein the dielectric layer is a first dielectric layer, and the semiconductor device further comprises a second dielectric layer covering the barrier layer, the first dielectric layer, and the gate layer.

4. The semiconductor device of claim 1, wherein the semiconductor device includes an isolation region and an active region, the gate layer being on the active region.

5. The semiconductor device of claim 4, wherein the isolation region extends at least across the barrier layer and the channel layer.

6. The semiconductor device of claim 5, wherein the isolation region extends into a first portion of the dielectric layer, and a second portion of the dielectric layer over the active region has different chemical compositions from the first portion.

7. The semiconductor device of claim 1, wherein the semiconductor layer includes a GaN buffer layer, and the barrier layer includes an AlGaN material.

8. The semiconductor device of claim 7, wherein the gate layer includes a p-type GaN material.

9. The semiconductor device of claim 7, wherein the gate layer includes a dielectric material.

10. A semiconductor device comprising:
a semiconductor layer having opposing first and second surfaces, the semiconductor layer including an isolation region and an active region;
a barrier layer on the first surface of the semiconductor layer, wherein the isolation region extends into the barrier layer, the isolation region includes ions, a concentration of the ions within the isolation region peaks at a depth below a surface of the barrier layer and drops from the depth towards the surface, the concentration of the ions at the surface being at least 10% of the concentration of the ions at the depth;
a gate layer on the barrier layer and in the active region; and
a dielectric layer on the gate layer.

11. The semiconductor device of claim 10, wherein the dielectric layer has a same footprint as the gate layer.

12. The semiconductor device of claim 10, wherein the dielectric layer is a first dielectric layer, and the semiconductor device further comprises a second dielectric layer covering the barrier layer, the first dielectric layer, and the gate layer.

13. The semiconductor device of claim 10, wherein the semiconductor device includes an isolation region and an active region, the gate layer being on the active region.

14. The semiconductor device of claim 13, wherein the isolation region extends into a first portion of the dielectric layer, and a second portion of the dielectric layer over the active region has different chemical compositions from the first portion.

15. The semiconductor device of claim 13, at least one of the barrier layer, the gate layer or the dielectric layer has a carbon concentration of 1×10¹⁶ cm⁻³ or less.

16. The semiconductor device of claim 10, wherein the semiconductor layer includes a GaN buffer layer, and the barrier layer includes an AlGaN material.

17. The semiconductor device of claim 16, wherein the gate layer includes a p-type GaN material.

18. The semiconductor device of claim 10, wherein the gate layer includes a dielectric material.

19. A semiconductor device comprising:
a semiconductor layer including an isolation region and an active region;
a barrier layer on the semiconductor layer;
a gate layer on the barrier layer and in the active region; and
a dielectric layer on the gate layer, in which the isolation region extends into a first portion of the dielectric layer, and a second portion of the dielectric layer over the active region has different chemical compositions from the first portion.

20. A method comprising:
forming a gate layer on a barrier layer and a semiconductor layer;
forming a dielectric layer on the gate layer;
forming a photoresist layer on the dielectric layer, in which the dielectric layer separates the gate layer from the photoresist layer;
patterning the photoresist layer;
performing an ion implantation operation on parts of the barrier layer and the semiconductor layer under the patterned photoresist layer; and
removing the patterned photoresist layer.

21. The method of claim 20, wherein the dielectric layer is a first dielectric layer, and the method further comprises:
after removing the photoresist layer, patterning the first dielectric layer and the gate layer; and
forming a second dielectric layer on the patterned first dielectric layer, the patterned gate layer, and the isolation region.

22. The method of claim 20, wherein the dielectric layer is a first dielectric layer, and the method further comprises:
patterning the first dielectric layer and the gate layer;
forming a second dielectric layer on the patterned first dielectric layer; and
wherein the photoresist layer is formed on the second dielectric layer, and the ion implantation is performed on a part of the second dielectric layer exposed by the patterned photoresist layer.

23. The method of claim 20, further comprising patterning the dielectric layer with the patterned photoresist, and the ion implantation is performed on a part of the barrier layer exposed by the patterned photoresist layer.
